(19) United States
(12) Patent Application Publication
(10) Pub. No.: US 2011/0186980 A1
(43) Pub. Date: Aug. 4, 2011

(54) Wireless Element With Antenna Formed On A Thin Film Substrate For Embedding into Semiconductor packages

(75) Inventor: Chang-Ming Lin, San Jose, CA (US)

(73) Assignee: RFMARQ, INC., Monte Sereno, CA (US)

(21) Appl. No.: 13/018,860

(22) Filed: Feb. 1, 2011

Related U.S. Application Data
(60) Provisional application No. 61/301,024, filed on Feb. 3, 2010.

(51) Int. Cl. H01L 23/48; G06K 19/06

(52) U.S. Cl. 257/690; 235/492; 257/E23.011

(57) ABSTRACT

In one embodiment, a wireless tag includes a wireless transceiver, a memory and an antenna all formed on a thin film substrate where the substrate includes one or more openings formed thereon. The opening in the substrate enables the flow of encapsulation material when the wireless tag is embedded into a semiconductor package. In another embodiment, a wireless tag is attached to the package substrate of a semiconductor package where the thin film substrate of the wireless tag has an opening sufficient to accommodate the integrated circuit die of the semiconductor package. In another embodiment, a wireless tag is formed using a metal film as the antenna and a wireless element attached to the metal film. The wireless tag is attached to the package substrate of a semiconductor package using a non-conductive adhesive. The metal film includes an opening sufficient to accommodate the die of the semiconductor package.

### CROSS-REFERENCE TO RELATED APPLICATIONS

This application claims the benefit of U.S. Provisional Patent Application Ser. No. 61/301,024, filed on Feb. 3, 2010, which application is incorporated herein by reference in its entirety.

### FIELD OF THE INVENTION

The invention relates to wireless communication devices and, in particular, the invention relates to wireless communication devices containing at least identification information and embedded in semiconductor packages.

### DESCRIPTION OF THE RELATED ART

Consumer electronic products can be tagged using electronic tracking devices or electronic tags to store product identity or other product information to allow the products to be tracked through the manufacturing process or through the supply and distribution chain. Electronic tags are read wirelessly by electronic readers (communicators) when the tags are within the communication range.

Radio frequency identification device (RFID) is an electronic tracking device commonly employed to track products and their movements. An RFID tag includes a wireless transceiver device, a memory and an antenna to enable radio frequency (RF) communication between the RFID tag and an RFID reader when the reader is brought within a communication range of the tag. The RFID transceiver device includes storage elements for storing identity or product information, and a circuit to receive incoming signals, generate response signals and transmit the response signals.

When RFID tags are affixed to electronic products, the RFID tags are often subject to easy tampering. For example, if the RFID tag is merely placed on the chassis or even on internal printed circuit board of an electronic product, the RFID tag can be removed to prevent tracking of the product.

Furthermore, the sensitivity of an RFID tag is related to the size of the antenna. For passive RFID tags that are driven by the electric energy converted from electro- magnetic wave via the antenna, the antenna is often designed with as large a length as possible to support the required power. That is, the antenna is designed to be as long as possible, usually by forming the antenna in loops. This makes RFID tag large in size and unsuitable for applications with limited real estate because the incorporation of a large antenna is not feasible.

### SUMMARY OF THE INVENTION

According to one embodiment of the present invention, a wireless tag for tracking product by using identity or identification information stored in the wireless tag includes a thin film substrate having one or more openings formed thereon; an antenna structure formed on the thin film substrate; and a wireless element including a wireless transceiver and a memory circuit formed as at least one integrated circuit die. The wireless element is electrically connected to the antenna structure where the memory circuit has at least identity or identification information stored thereon. The wireless transceiver and the antenna structure operate in conjunction to enable the information stored in the memory circuit to be accessed through wireless communication.

According to another embodiment of the present invention, a semiconductor package includes a package substrate; a first integrated circuit die housed on or in the package substrate and electrically connected to leads of the semiconductor package; and a wireless tag including a wireless element and an antenna formed on a thin film substrate. The thin film substrate has at least one opening formed thereon. The wireless element includes a wireless transceiver and a memory circuit both formed as at least a second integrated circuit die. The semiconductor package further includes an encapsulation layer encapsulating at least the wireless tag. The wireless tag is affixed to the package substrate and is electrically insulated from electrical connections formed between the first integrated circuit die and the leads of the semiconductor package. The opening in the thin film substrate has a size sufficient to accommodate at least the first integrated circuit die. The wireless transceiver and the antenna operate in conjunction to enable the information stored in the memory circuit to be accessed through wireless communication.

According to another embodiment of the present invention, a semiconductor package including a package substrate; a first integrated circuit die housed on or in the package substrate and electrically connected to leads of the semiconductor package; and a wireless tag including an antenna formed as a metal film and a wireless element attached to the antenna. The metal film has at least one opening formed thereon. The wireless element includes a wireless transceiver and a memory circuit both formed as at least a second integrated circuit die. The semiconductor package further includes an encapsulation layer encapsulating at least the wireless tag. The wireless tag is affixed to the package substrate and is electrically insulated from electrical connections formed between the first integrated circuit die and the leads of the semiconductor package. The opening in the metal film of the antenna has a size sufficient to accommodate at least the first integrated circuit die. The wireless transceiver and the antenna operate in conjunction to enable the information stored in the memory circuit to be accessed through wireless communication.

### BRIEF DESCRIPTION OF THE DRAWINGS

FIGS. 1(a) and 1(b) are cross-sectional and perspective views of a wireless tag formed using a thin film substrate according to one embodiment of the present invention.

FIGS. 2(a) and 2(b) are cross-sectional views of a semiconductor package incorporating a wireless tag with an intact substrate illustrating void formation.

FIG. 3 is a top view of a wireless tag formed using a thin film substrate according to one embodiment of the present invention.

FIG. 4 is a top view of a wireless tag formed using a thin film substrate according to another embodiment of the present invention.

FIG. 5 illustrates a series of antenna structures formed using a metal film according to one embodiment of the present invention.

FIGS. 6(a) to 6(c) are top and cross-sectional views of a wireless tag embedded in a semiconductor package according to one embodiment of the present invention.

FIGS. 7(a) to 7(c) are top and cross-sectional views of a wireless tag embedded in a semiconductor package according to another embodiment of the present invention.

FIGS. 8(a) to 8(c) are top and cross-sectional views of a wireless tag embedded in a semiconductor package according to another embodiment of the present invention.

FIGS. 9(a) to 9(c) are top and cross-sectional views of a wireless tag embedded in a semiconductor package according to another embodiment of the present invention.

### DETAILED DESCRIPTION OF THE PREFERRED EMBODIMENTS

According to one aspect of the present invention, a wireless tag includes a wireless transceiver, a memory and an antenna all formed on a thin film substrate where the thin film substrate is provided with one or more openings or holes. The wireless tag is inserted into the packaging material of a microelectronic device to implement tracking and authentication functions for the microelectronic device and/or the derivative electronic system incorporating this microelectronic device. As thus structured, the voids or openings in the thin film substrate allow the substrate to be permeable to the package encapsulation material. Accordingly, when the wireless tag is incorporated into the packaging material of a microelectronic device, the packaging material is able to flow through the openings of the substrate so that voids do not form in the encapsulation material underneath the wireless tag's substrate. The assembly process reliability of the microelectornic device incorporating the wireless communication device is improved.

In some embodiments, the thin film substrate on which the wireless transceiver, the memory and the antenna are formed is a flexible substrate. In some embodiments, the flexible substrate is formed from polymer films. Examples of this polymer films include, but are not limited to, polyethylene terephthalate (PET), Kapton, polyimide or mylar flexible polymer films. In other embodiments, the thin film substrate is a thin rigid substrate. For instance, the thin rigid substrate may be formed of an oxide material including glass or ceramic. The thin rigid substrate may also be formed using composite materials, such as acrylic polymers, rigid polymers, polymer composites, or FR4 with glass fiber. In some embodiments, the thin rigid substrate has a thickness of less than 1 mil to several mils.

According to another aspect of the present invention, a wireless tag formed on a flexible substrate with one or more openings is attached to the package body of the microelectronic device. The opening of the flexible substrate is configured to accommodate or encircle at least one integrated circuit die of the microelectronic device. The wireless tag may then be encapsulated with the integrated circuit die or independently encapsulated.

According to yet another aspect of the present invention, a wireless tag includes an antenna formed as a metal film and a wireless element including a wireless transceiver and a memory formed as an integrated circuit die and attached to the metal film. The wireless tag is incorporated into a semiconductor device with the metal film attached to the package body of the microelectronic device. The metal film is formed with one or more openings which are configured to accommodate or encircle at least one integrated circuit die of the microelectronic device. The wireless tag may then be encapsulated with the integrated circuit chip or independently encapsulated.

In some embodiments, the wireless tag stores identity or other identification information for the microelectronic device, and/or the derivative system product incorporating the microelectronic device. In this manner, the same wireless tag can be used to track and authenticate the microelectronic device as well as the derivative system products incorporating the microelectronic device. More specifically, the information stored in the memory of the wireless tag may be accessed by a wireless reader when the wireless tag comes within the communication range of the reader. For instance, the information stored in the memory may be accessed in order to read out or to alter the stored information.

The wireless tag of the present invention can be readily adapted for use in a variety of semiconductor package types to allow tracking and authentication function to be implemented. Furthermore, by embedding the wireless tag into the packaging of the microelectronic device, the wireless tag is protected from tampering, further ensuring the authenticity of the microelectronic device and/or its derivative system product.

In embodiments of the present invention, a microelectronic device includes semiconductor packages containing a single integrated circuit die or multiple integrated circuit die. The semiconductor packages may be formed of various materials, including plastic, ceramic, and other semiconductor packaging materials. A semiconductor package housing two or more integrated circuits die (or “IC chips”) is sometimes referred to as a multi-chip package (MCP) or a MCP module or a multi-chip module (MCM). Examples of semiconductor packages in which the wireless tag of the present invention can be embedded include plastic ball grid array (PBGA) packages, ceramic ball grid array (CBGA) packages, land grid array (LGA) packages, plastic quad flat packages (PQFP), low-profile quad flat packages (LQFP), and other semiconductor packages. In the present description, the term “semiconductor package” refers to both single chip packages or multi-chip packages (MCP).

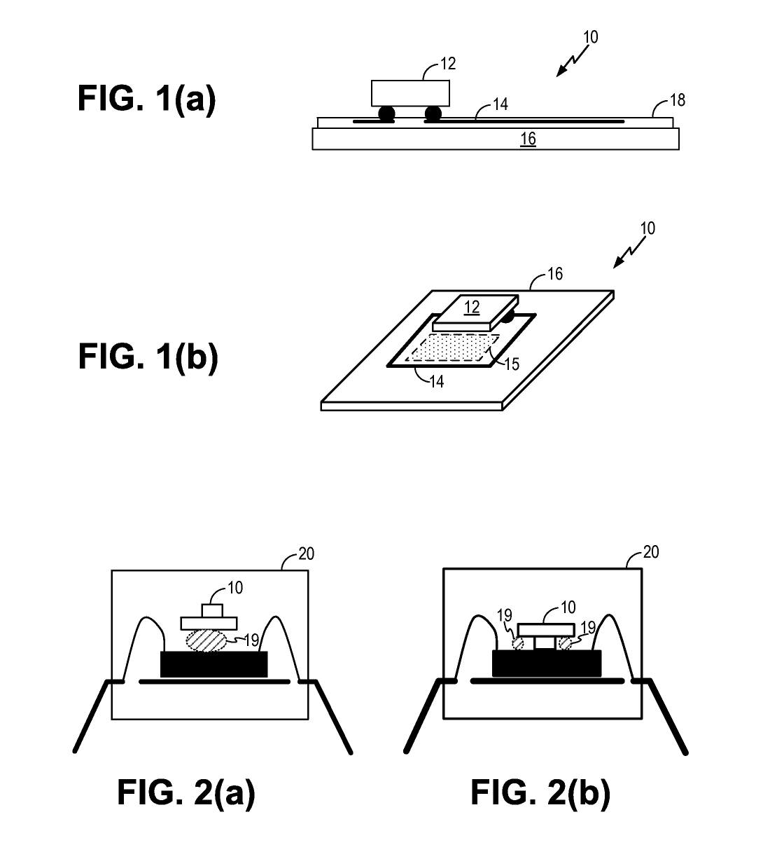

In embodiments of the present invention, a wireless tag is preformed or manufactured as a standalone element for embedding into a semiconductor package. The wireless tag includes a wireless element including a wireless transceiver and a memory circuit typically formed as an integrated circuit die. FIGS. 1(a) and 1(b) are cross-sectional and perspective views of a wireless tag (“a wireless tag”) formed using a thin film substrate according to one embodiment of the present invention. Referring to FIGS. 1(a) and 1(b), a wireless tag 10 includes a wireless transceiver and a memory, referred to collectively as a wireless element 12, which are formed as a single integrated circuit die. The wireless element 12 and a metallic antenna structure 14 are formed on a thin film substrate 16 which can be a flexible substrate or a thin rigid substrate. In the present embodiment, the wireless element 12 is flip-chip attached to the antenna structure 14. In one embodiment, the wireless element 12 is affixed to the antenna structure using solder-bump reflow.

In some embodiments, the metallic antenna structure 14 is formed using a single layer of metal film or using a multi-layer metal structure with intercalated dielectric films as isolation and interconnect via(s) to bridge different metal layers. The metal film may be a monolithic metal film. In some embodiments, the metal film is formed of a material selected from copper, aluminum, other conductive metal or alloy films. The metal films and dielectric films can be formed using sputtering deposition, evaporation coating, electroplating, laminating or printing or other deposition methods. In one embodiment, the antenna structure is formed by depositing a metal film into a pattern preformed by photoresist (or equivalent materials). In another embodiment, the antenna structure is formed by depositing a metal layer on the substrate and patterning or masking the metal layer using a photoresist. The masked metal layer can then be processed using etching techniques, including wet metal etch or dry metal etch or a combination of both. In some embodiments, a passivation dielectric layer 18 is formed over the metallic antenna structure 14 to protect the as-fabricated antenna structure. However, the passivation dielectric layer 18 is optional and may be omitted in other embodiments of the present invention. The above-described metal antenna fabrication methods are illustrative only and are not intended to be limiting. Other fabrication methods for forming the metal antenna can be used.

In the present embodiment, the wireless element 12 of the wireless tag 10 is affixed to contact pads of the metallic antenna structure 14 by means of flip-chip attachment as shown in FIGS. 1(a) and 1(b). The flip-chip attachment can be accomplished using a variety of techniques, including anisotropic conductive adhesives (ACA), conductive inks, conductive pastes, gold bumps, solder bumps, or other bumps formed by low melting point metals or alloys. In some embodiments, an underfiller and/or a globtop material may be applied to further enhance the mechanical bonding integrity of the electrically conductive joints between wireless element and the antenna contact pads. In other embodiments, other methods for affixing the wireless element 12 to the antenna structure 14 may be used. The use of flip-chip attachment is illustrative only and is not intended to be limiting.

In some embodiments of the present invention, one or more openings 15 are formed in the substrate 16. The opening 15 is formed in an area of the substrate 16 not covered by any antenna structure 14. For instance, because antenna structure 14 is typically formed in the shape of a loop, the central area of the substrate encircled by an antenna loop is not used and an opening 15 can be formed in the central unused area, as shown by the shaded area in FIG. 1(b). In some embodiments, opening 15 is formed by punching or lasing (i.e. laser cutting). Opening 15 can also be formed using etching of the substrate, including plasma etching, chemical etching, reactive ion etching, ion milling or any permutation combination of them. Other suitable methods for removing a portion of the substrate to form an opening may also be used.

By providing the opening 15 in the substrate 16, the wireless tag 10 is made compatible with assembly processes using encapsulation materials such as plastic molding compound, glob-top polymer, silicone, or thermal grease encapsulation. In an assembly process using an encapsulation, when a wireless tag is incorporated into the semiconductor package and the thin film substrate of the wireless tag is completely intact, the substrate may impede the flow of polymer fluids such as air bubbles or voids are formed between the substrate of the wireless tag and the underlying integrated circuit structure, as shown in FIGS. 2(a) and 2(b). The trapped air bubbles or voids 19 in the encapsulation material of a semiconductor package 20 are undesirable as they may impact the long-term reliability of the semiconductor package.

In accordance with embodiments of the present invention, the wireless tag 10 is formed with openings or holes in the substrate 16 to render the substrate permeable to the encapsulation materials. That is, the encapsulation materials may flow through the substrate of the wireless tag during the encapsulation process so that trapped air bubbles or voids in the final encapsulation structure are entirely avoided. As thus formed, a stand-alone wireless tag 10 can be embedded into a semiconductor package to enable tracking and authenticating functions. The preformed wireless tag can be inserted into encapsulation material of a semiconductor package. In order for the wireless tag to be incorporated into a semiconductor package, the wireless tag is typically no larger and no thicker than the size of the semiconductor package.

In the above-described embodiment, a single integrated circuit die (wireless element 12) houses both the wireless transceiver and the memory. In other embodiments, the wireless transceiver and the memory circuit can be formed as two or more integrated circuits dies, all of the integrated circuits being interconnected on the thin film substrate to form the wireless tag. The exact level of integration of the wireless transceiver and the memory of the wireless tag is not critical to the practice of the present invention. In the present description, the term “a wireless element” refers to the combination of a wireless transceiver circuit and a memory circuit formed in one or more integrated circuit die.

Furthermore, in the above-described embodiments, the integrated circuit(s) forming the wireless element is flip-chip attached to the substrate. In other embodiments, the integrated circuit(s) of the wireless element may be attached to the thin film substrate and then electrically connected to the antenna or other metal interconnects (if any) through other bonding and electrical connection techniques, including wire bonding. In some embodiments, the integrated circuit(s) of the wireless element is attached to the substrate using die attach and then the integrated circuits are wire bonded to the antenna and the metal interconnects (if any). In some embodiments, a globtop material or suitable polymer, such as epoxy or silicone, may be applied to protect the wire bonds.

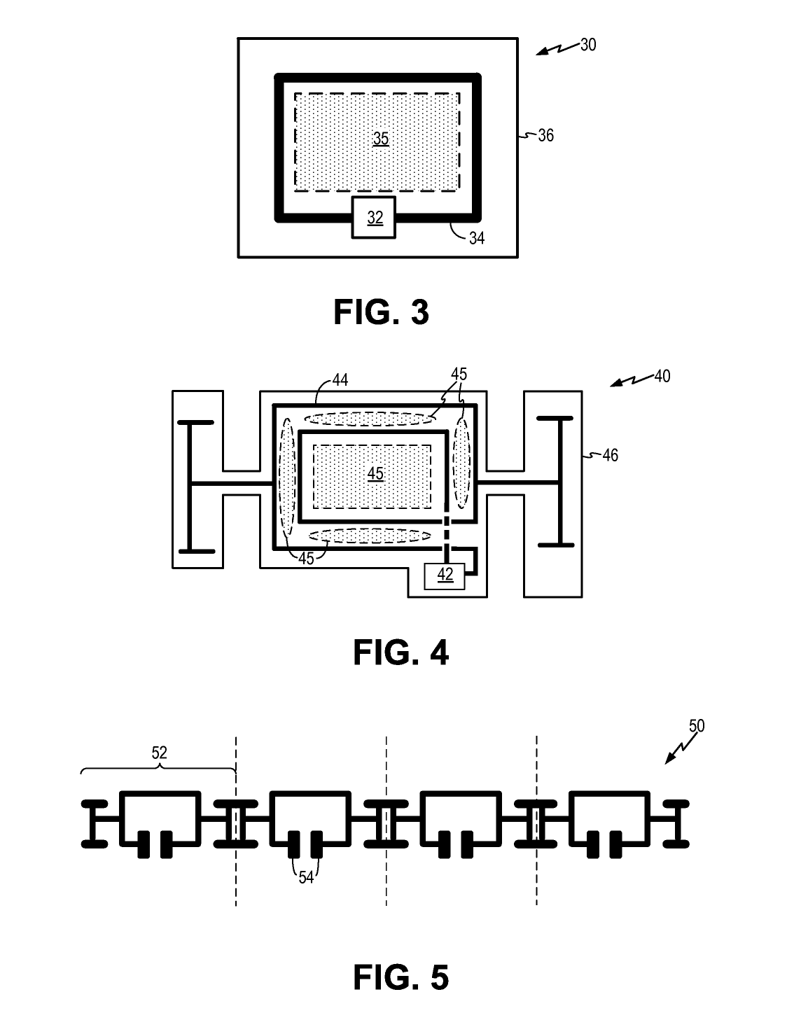

FIG. 3 is a top view of a wireless tag formed using a thin film substrate according to one embodiment of the present invention. Referring to FIG. 3, a wireless tag 30 includes a wireless element 32 electrically connected to an antenna 34 formed on a thin film substrate 36 which may be a flexible substrate or a thin rigid substrate. In the present embodiment, the antenna 34 is formed as a single metal layer on substrate 36. An opening 35 is formed in a central area of the substrate 36 around the contour of the antenna 34. The opening 35 allows encapsulation materials to flow through during the assembly process so as to avoid formation of air bubbles in the packaged semiconductor package.

FIG. 4 is a top view of a wireless tag formed using a thin film substrate according to another embodiment of the present invention. Referring to FIG. 4, a wireless tag 40 includes a wireless element 42 electrically connected to an antenna 44 formed on a thin film substrate 46 which may be a flexible substrate or a thin rigid substrate. In the present embodiment, the antenna 34 is formed as multiple metal layers on substrate 46. Multiple openings 45 are formed in areas of the substrate 46 not used by antenna 44. The openings 45 follow the contour of the antenna 44. The openings 45 allow encapsulation materials to flow through during the assembly process so as to avoid formation of air bubbles in the packaged semiconductor package.

In the above described embodiments, the opening in the substrate is shown as having a rectangular or oval shape. The shapes shown in the figures are illustrative only. In other embodiments, the openings in the substrate can have any shape suitable to accommodate the antenna structure while providing the desired amount of permeability. In general, the shape of the openings can follow the contour of the antenna to make use of most of the unused space on the substrate as openings.

According to yet another aspect of the present invention, a single layer antenna structure can be formed as a series of individual antenna units connected via narrow metal bridges on a strip of thin metal foil in the same manner as a TAB tape. At this stage, there is no polymer or any dielectric material to carry or passivate the antenna structure. FIG. 5 illustrates a series of antenna structures formed using a metal film according to one embodiment of the present invention. Referring to FIG. 5, a metal frame 50 includes a series of antenna structures 52 connected serially through metal bridges. Each antenna structure 52 includes a pair of bonding pads 54 for connecting to a wireless element. The wireless element may be flip chip attached to the bonding pads 54 or attached to the bonding pads through bond wires. After a wireless element is attached to each antenna structure 52 of the metal frame 50, the narrow metal bridge frames connecting each antenna structure can then be disconnected, such as by use of trimming or other separation method. When separated, the individual unit with a wireless element and the antenna functions as a standalone wireless tag. In some embodiments, the as-fabricated individual unit can be coated with a polymer or dielectric film for electrical isolation.

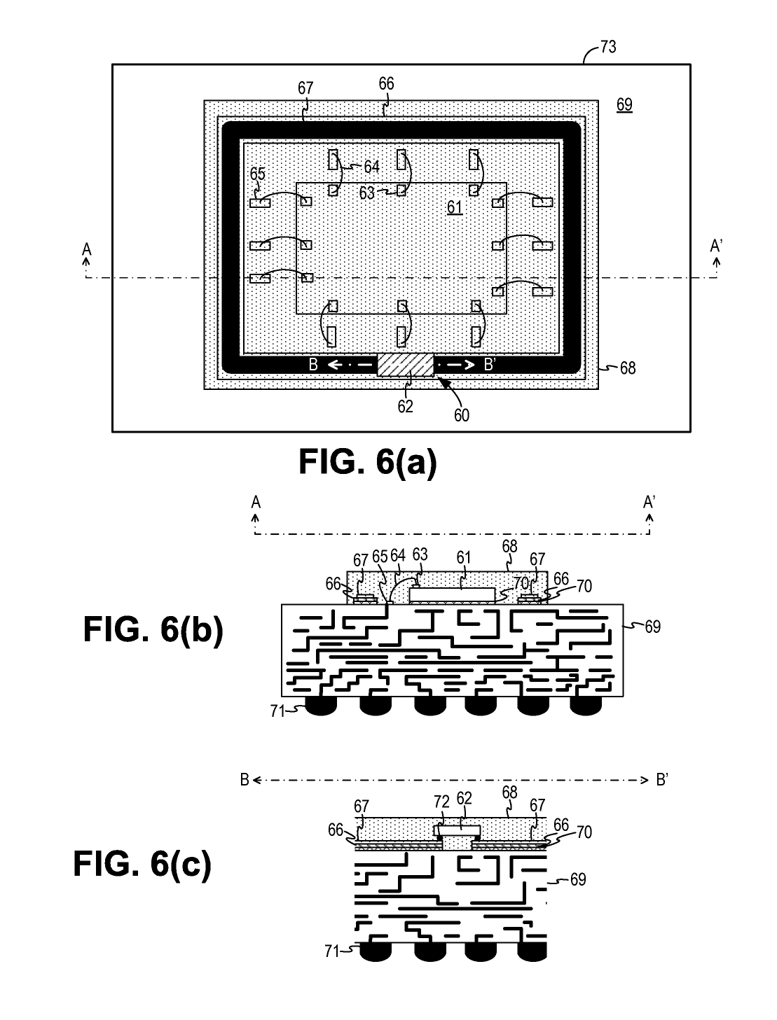

FIGS. 6(a) to 6(c) are top and cross-sectional views of a wireless tag embedded in a semiconductor package according to one embodiment of the present invention. Referring to FIGS. 6(a) to 6(c), a wireless tag 60 is embedded in a thin film ball grid array (BGA) package 73 housing an integrated circuit (IC) die 61. BGA package 73 includes a package substrate 69 formed as a multilayer interconnect substrate for connecting the input/output pads of IC die 61 to the BGA solder balls 71. More specifically, bond wires 64 connect bonding pads 63 on IC die 61 to bonding fingers 65 of the package substrate 69. The wireless tag 60 includes a wireless element 62 electrically connected to an antenna 67 all formed on a thin film substrate 66 which can be a flexible substrate or a thin rigid substrate. In the present embodiment, the wireless element 62 is flip-chip attached to the antenna 67 through solder or conductive adhesive joints 72. In other embodiments, the wireless element 62 can be electrically connected to the antenna 67 using other means, such as using bond wires.

The thin film substrate 66 is provided with an opening sufficient to accommodate or encircle the integrated circuit chip 61 and the bonding fingers 65 of the package substrate 69. As thus configured, the wireless tag 60 is attached to the package substrate, such as by the use of a die attach material 70, outside of the bonding fingers 65. Physical contact between the wireless tag 60 and the bond wires 64 is thus avoided. In the present embodiment, the IC die 61 and the wireless tag 60 are both encapsulated by an encapsulant 68. Encapsulant 68 may be a transparent encapsulation material or an opaque encapsulation material.

As thus configured, the physical form factor, especially the total height, of the thin film BGA package 73 remains the same even with the embedding of wireless tag 60.

The wireless tag embedding method shown in FIGS. 6(a) to 6(c) can be applied to other plastic encapsulated semiconductor packages, such as plastic molded lead frame packages or plastic quad flat packages or low-profile quad flat packages.

According to embodiments of the present invention, the thin film BGA package 73 is a multi-chip package including two or more IC die. The wireless tag 60 may be formed with an opening sufficient to encircle one of the IC die or multiple IC dies or all of the IC die of the package.

Furthermore, in the above-described embodiment, the wireless tag is a preformed wireless tag with the wireless element attached to the antenna and then the preformed tag is then affixed to the package substrate. In other embodiments of the present invention, a wireless tag is not preformed but rather is formed during the embedding process. More specifically, the thin firm substrate 66 with the antenna 67 formed thereon may be first affixed to the package substrate. Then the wireless element 62 is electrically connected to the antenna 67 to form wireless tag 60. The resulting wireless tag operates in the same manner as a preformed wireless tag and enables product tracking and identification functions.

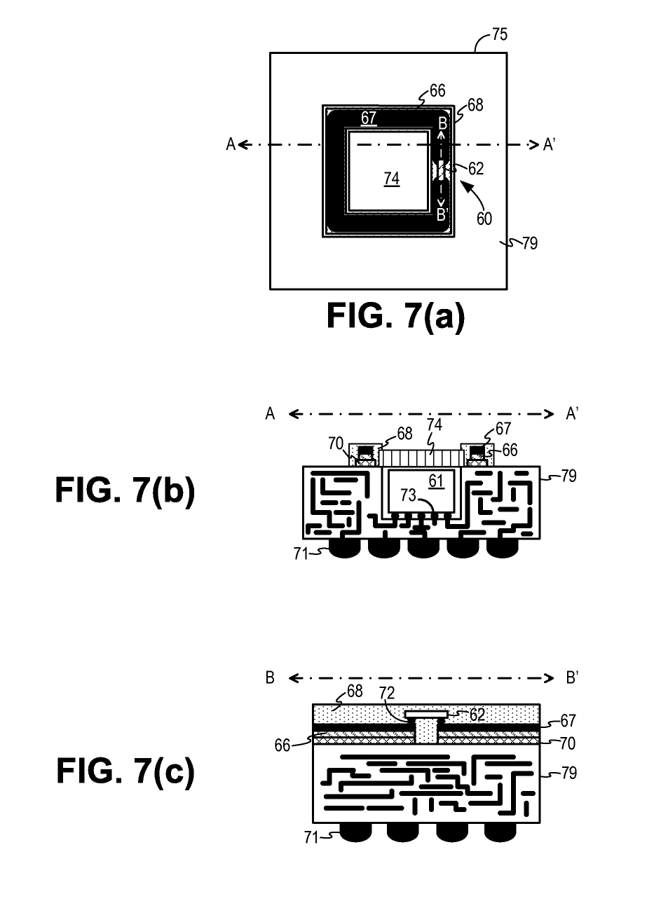

FIGS. 7(a) to 7(c) are top and cross-sectional views of a wireless tag embedded in a semiconductor package according to another embodiment of the present invention. Referring to FIGS. 7(a) to 7(c), a wireless tag 60 is embedded in a cavity up ball grid array (BGA) package 75 housing an integrated circuit (IC) die 61. BGA package 75 includes a package substrate 79 formed as a multilayer interconnect substrate for connecting the input/output pads of IC die 61 to the BGA solder balls 71 through solder bumps 73. The cavity of the package substrate 79 is sealed by a package lid 74.

The wireless tag 60 includes a wireless element 62 electrically connected to an antenna 67 all formed on a thin film substrate 66 which can be a flexible substrate or a thin rigid substrate. In the present embodiment, the wireless element 62 is flip-chip attached to the antenna 67 through solder or conductive adhesive joints 72. In other embodiments, the wireless element 62 can be electrically connected to the antenna 67 using other means, such as using bond wires.

The thin film substrate 66 is provided with an opening sufficient to accommodate the package lid 74 of BGA package 75. As thus configured, the wireless tag 60 is attached to a top surface of the package 75, such as by the use of a die attach material 70. The wireless tag 60 includes an opening large enough to accommodate the package lid 74 and is attached to the package surface after the lid sealing process. In the present embodiment, the wireless tag 60 is encapsulated by an encapsulant 68. In some embodiments, encapsulant 68 is a non-transparent encapsulation material, such as organic or inorganic compounds. In some embodiments, the encapsulant 68 can be formed using a material selected from epoxy, globtop, low melting point glass fits, silicone and other similar encapsulation materials which can be visually opaque or transparent.

As thus configured, the physical form factor, especially the total height, of the cavity up BGA package 75 remains intact even with the embedding of wireless tag 60. Furthermore, by attaching the wireless tag 60 to the surface of the package substrate 79, shielding effect by the metallic package lid is avoided and the wireless communication capability of the wireless tag 60 is preserved.

The wireless tag embedding method shown in FIGS. 7(a) to 7(c) can be applied to other high density interconnect packages, including cavity down BGA packages, cavity up column grid array (CGA) packages, cavity down CGA package, cavity up pin grid array (PGA) packages, cavity down PGA packages, and other similar packages.

Furthermore, in the above-described embodiment, the wireless tag is a preformed wireless tag with the wireless element attached to the antenna and then the preformed tag is then affixed to the package surface. In other embodiments of the present invention, a wireless tag is not preformed but rather is formed during the embedding process. More specifically, the thin firm substrate 66 with the antenna 67 formed thereon may be first affixed to the package surface. Then the wireless element 62 is electrically connected to the antenna 67 to form wireless tag 60.

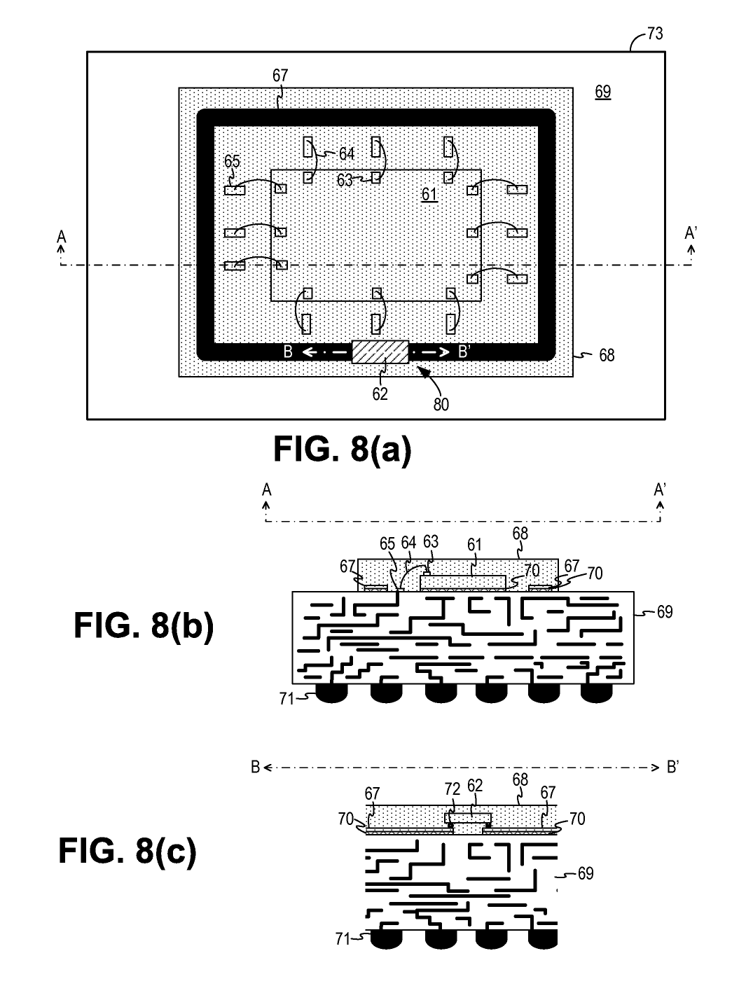

FIGS. 8(a) to 8(c) are top and cross-sectional views of a wireless tag embedded in a semiconductor package according to another embodiment of the present invention. Referring to FIGS. 8(a) to 8(c), a wireless tag 80 is embedded in a thin film ball grid array (BGA) package 73 housing an integrated circuit (IC) die 61. The wireless tag embedding method shown in FIGS. 8(a) to 8(c) is the same as that shown and described with respect to FIGS. 6(a) to 6(c) except that the wireless tag 80 in the present embodiment is formed without a substrate. More specifically, the wireless tag 80 includes a wireless element 62 electrically connected to an antenna 67 formed as a metal film. The antenna 67 can be formed from a metal layer using one of many metal patterning processes, including mechanical stamping, mechanical punching, lasing, wet etching with photoresist mask or other similar processing methods. In the present embodiment, the wireless element 62 is flip-chip attached to the antenna 67 through solder or conductive adhesive joints 72. In other embodiments, the wireless element 62 can be electrically connected to the antenna 67 using other means, such as using bond wires.

The antenna 67 is formed with an opening sufficient to accommodate the integrated circuit chip 61 and the bonding fingers 65 of package substrate 69. As thus configured, the wireless tag 80 is attached to the package substrate, such as by the use of a die attach material 70, outside of the bonding fingers 65. In the present embodiment, the die attach material 70 is a non-electrically conductive die attach material or adhesive as the antenna 67 is formed without an insulating substrate. Physical contact between the wireless tag 80 and the bond wires 64 of the BGA package 73 is thus avoided. In the present embodiment, the IC die 61 and the wireless tag 80 are both encapsulated by an encapsulant 68, in the same manner as described above.

The wireless tag embedding method shown in FIGS. 8(a) to 8(c) can be applied to other plastic encapsulated semiconductor packages, such as plastic molded lead frame packages or plastic quad flat packages.

According to embodiments of the present invention, the thin film BGA package 73 is a multi-chip package including two or more IC die. The wireless tag 80 may be formed with an opening sufficient to encircle one of the IC die or multiple IC dies or all of the IC die of the package.

Furthermore, in the above-described embodiment, the wireless tag is a preformed wireless tag with the wireless element electrically attached to the antenna and then the preformed tag is then affixed to the package substrate. In other embodiments of the present invention, a wireless tag is not preformed but rather is formed during the embedding process. More specifically, the thin firm substrate 66 with the antenna 67 formed thereon may be first affixed to the package substrate. Then the wireless element 62 is electrically connected to the antenna 67 to form wireless tag 80.

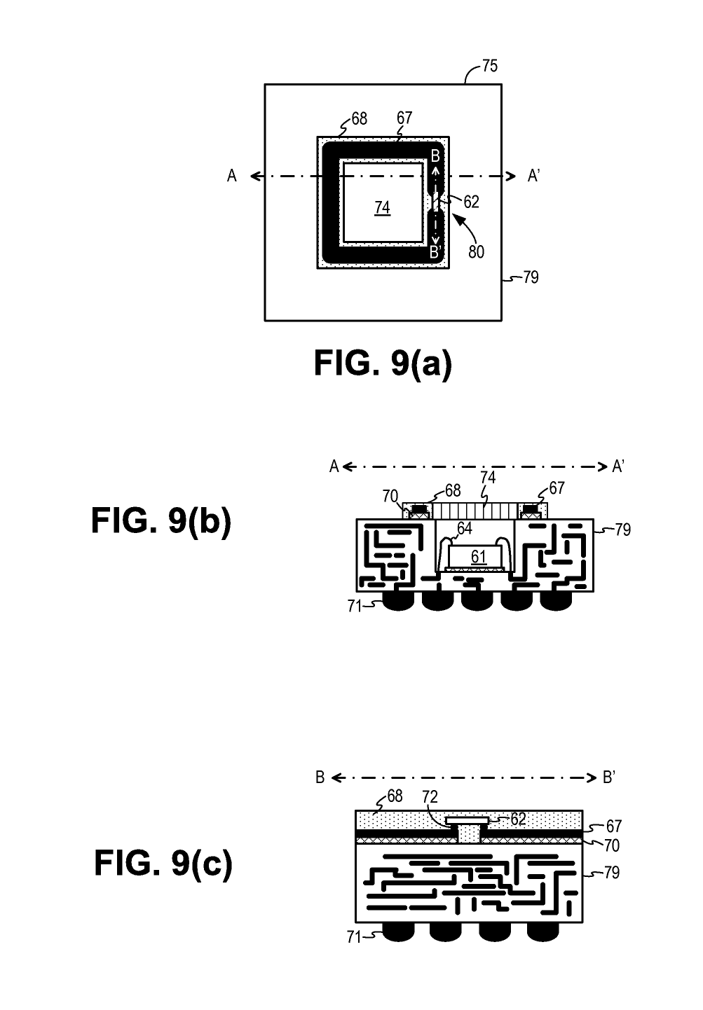

FIGS. 9(a) to 9(c) are top and cross-sectional views of a wireless tag embedded in a semiconductor package according to another embodiment of the present invention. Referring to FIGS. 9(a) to 9(c), a wireless tag 80 is embedded in a cavity up ball grid array (BGA) package 75 housing an integrated circuit (IC) die 61. The wireless tag embedding method shown in FIGS. 9(a) to 9(c) is the same as that shown and described with respect to FIGS. 7(a) to 7(c) except that the wireless tag 80 in the present embodiment is formed without a substrate. More specifically, the wireless tag 80 includes a wireless element 62 electrically connected to an antenna 67 formed as a metal film, as described above with reference to FIGS. 8(a) to 8(c).

The antenna 67 is provided with an opening sufficient to accommodate the package lid 74 of BGA package 75. As thus configured, the wireless tag 80 is attached to the surface of the package substrate, such as by the use of a non-conductive die attach material 70 or adhesive. The wireless tag 80 includes an opening large enough to accommodate the package lid 74 and is attached to the package surface after the lid sealing process. In the present embodiment, the wireless tag 80 is encapsulated by an encapsulant 68, in the same manner as described above with reference to FIGS. 7(a) to 7(c).

Furthermore, in the above-described embodiment, the wireless tag is a preformed wireless tag with the wireless element electrically connected to the antenna and then the preformed tag is then affixed to the package surface. In other embodiments of the present invention, a wireless tag is not preformed but rather is formed during the embedding process. More specifically, the metal film antenna 67 may be first affixed to the package surface. Then the wireless element 62 is electrically connected to the antenna 67 to form wireless tag 80.

In the above-described embodiments, the semiconductor package is shown as housing a single integrated circuit die only. The single-die semiconductor package is illustrative only. The wireless tag described herein can be applied to semiconductor packages housing two or more integrated circuit dies, such as multi-chip packages.

In embodiments of the present invention, the wireless tag stores at least identity or identification information of the microelectronic device in the memory of the wireless element of the wireless tag. In other embodiments, the wireless tag stores at least identity or identification information of the derivative system products incorporating the microelectronic device in the memory of the wireless element of the wireless tag. In the present description, “identity” or “identification information” of a microelectronic device includes at least one of the identification number, part number, model number, model name, brand name, maker, logo design, and production and/or distribution history of the microelectronic device. Furthermore, identity or identification information can include a software code or an algorithm to generate an identity code in response to interrogations from a wireless reader or other systems. In embodiments of the present invention, the data format of the identification information includes a random or serial numerical numbers or characters, logo marks, graphic symbols, 2D graphic codes, or any multiplex permutation of these formats. Other encoding or algorithms methods currently known or to be developed can also be used. In an alternate embodiment, the identity or identification information stored in the wireless element is protected through the use of encryption or software keys or other feasible security protection methods presently known or to be developed.

Also, in the present embodiment, the wireless tag is capable of wireless communication employing one or more of the wireless communication technologies currently known or to be developed. For example, in one embodiment, the wireless tag implements wireless communication through radio frequency (RF) communication, such as based on the RFID (radio frequency identification) technology, or wireless local area network communication technology, such as Wi-Fi technology. In another embodiment, the wireless tag employs Bluetooth radio technology. Bluetooth radio technology is an open specification for short-range wireless communication of data and voice that operates in the unlicensed Industrial, Scientific, Medical (ISM) band at 2.4 Gigahertz (GHz). The gross data rate may be 1 megabit per second (Mb/s). In yet another embodiment, the wireless tag employs ZigBee communication technology. ZigBee is a wireless control technology utilizing a low-cost, low power, wireless mesh networking protocol that is especially useful in control and monitoring applications. In yet another embodiment, the wireless tag employs WiMAX communication.

The above detailed descriptions are provided to illustrate specific embodiments of the present invention and are not intended to be limiting. Numerous modifications and variations within the scope of the present invention are possible. The present invention is defined by the appended claims.

I claim:

1. A wireless tag for tracking products by using identity or identification information stored in the wireless tag, the wireless tag comprising:
a thin film substrate having one or more openings formed thereon;
an antenna structure formed on the thin film substrate; and
a wireless element including a wireless transceiver and a memory circuit formed as at least one integrated circuit die, the wireless element being electrically connected to the antenna structure, the memory circuit having at least identity or identification information stored thereon,
wherein the wireless transceiver and the antenna structure operate in conjunction to enable the information stored in the memory circuit to be accessed through wireless communication.

2. The wireless tag of claim 1, wherein the one or more openings are formed along contours of the antenna structure to substantially cover areas of the thin film substrate not used by the antenna structure.

3. The wireless tag of claim 1, wherein the thin film substrate comprises a flexible thin film substrate.

4. The wireless tag of claim 3, wherein the flexible thin film substrate is formed of a polymer film.

5. The wireless tag of claim 4, wherein the flexible thin film substrate is formed of a material selected from polyethylene terephthalate (PET), Kapton, polyimide or mylar flexible polymer film.

6. The wireless tag of claim 1, wherein the thin film substrate comprises a thin rigid substrate formed of a material selected from ceramic, glass, acrylic polymers, rigid polymers, or polymer composites.

7. The wireless tag of claim 1, wherein the antenna structure comprises a single layer of metal film formed on the thin film substrate.

8. The wireless tag of claim 1, wherein the antenna structure comprises a multi-layer metal structure with intercalated dielectric films formed on the thin film substrate.

9. The wireless tag of claim 1, further comprising a passivation layer formed over the antenna structure.

10. The wireless tag of claim 1, wherein the integrated circuit die of the wireless element is affixed to the antenna structure through flip-chip attachment.

11. The wireless tag of claim 1, wherein the integrated circuit die of the wireless element is affixed to the thin film substrate using die attach, the integrated circuit die being electrically connected to the antenna structure through wire bonds.

12. The wireless tag of claim 1, wherein the wireless transceiver comprises a radio frequency (RF) transceiver.

13. A semiconductor package, comprising:
a package substrate;
a first integrated circuit die housed on or in the package substrate and electrically connected to leads of the semiconductor package;
a wireless tag comprising a wireless element and an antenna formed on a thin film substrate, the thin film substrate having at least one opening formed thereon, the wireless element including a wireless transceiver and a memory circuit both formed as at least a second integrated circuit die, and
an encapsulation layer encapsulating at least the wireless tag,
wherein the wireless tag is affixed to the package substrate and is electrically insulated from electrical connections formed between the first integrated circuit die and the leads of the semiconductor package, the opening in the thin film substrate having a size sufficient to accommodate at least the first integrated circuit die; and
wherein the wireless transceiver and the antenna operate in conjunction to enable the information stored in the memory circuit to be accessed through wireless communication.

14. The semiconductor package of claim 13, wherein the first integrated circuit die is electrically connected to leads of the semiconductor package through bond wires connecting bond pads on the first integrated circuit die to bonding fingers on the package substrate, wherein the opening in the thin film substrate has a size sufficient to expose the first integrated circuit and the bonding fingers so that the antenna is formed outside of the bonding fingers.

15. The semiconductor package of claim 14, wherein the encapsulation layer encapsulates the first integrated circuit die and the wireless tag.

16. The semiconductor package of claim 13, wherein the encapsulation layer comprises a transparent encapsulation layer.

17. The semiconductor package of claim 13, wherein the package substrate comprises a cavity in which the first integrated circuit die is housed, the semiconductor package further comprising a package lid sealing the cavity; and wherein the wireless tag is attached to a surface of the package substrate surrounding the package lid, the opening in the thin film substrate having a size sufficient to expose the package lid.

18. The semiconductor package of claim 17, wherein the encapsulation layer encapsulates the wireless tag only.

19. The semiconductor package of claim 13, wherein the thin film substrate comprises a flexible thin film substrate.

20. The semiconductor package of claim 19, wherein the flexible thin film substrate is formed of a material selected from polymer films, polyethylene terephthalate (PET), Kapton, polyimide or mylar flexible polymer film.

21. The semiconductor package of claim 13, wherein the thin film substrate comprises a thin rigid substrate formed of a material selected from ceramic, glass, acrylic polymers, rigid polymers, or polymer composites.

22. The semiconductor package of claim 13, wherein the second integrated circuit die of the wireless element is affixed to the antenna through flip-chip attachment.

23. A semiconductor package, comprising:
a package substrate;
a first integrated circuit die housed on or in the package substrate and electrically connected to leads of the semiconductor package;
a wireless tag comprising an antenna formed as a metal film and a wireless element attached and electrically connected to the antenna, the metal film having at least one opening formed thereon, the wireless element including a wireless transceiver and a memory circuit both formed as at least a second integrated circuit die, and
an encapsulation layer encapsulating at least the wireless tag,
wherein the wireless tag is affixed to the package substrate and is electrically insulated from electrical connections formed between the first integrated circuit die and the leads of the semiconductor package, the opening in the metal film of the antenna having a size sufficient to accommodate at least the first integrated circuit die; and
wherein the wireless transceiver and the antenna operate in conjunction to enable the information stored in the memory circuit to be accessed through wireless communication.

24. The semiconductor package of claim 23, wherein the wireless tag is attached to the package substrate using a non-electrically conductive adhesive.

25. The semiconductor package of claim 23, wherein the first integrated circuit die is electrically connected to leads of the semiconductor package through bond wires connecting bond pads on the first integrated circuit die to bonding fingers on the package substrate, wherein the opening in the metal film has a size sufficient to expose the first integrated circuit and the bonding fingers so that the antenna is formed outside of the bonding fingers.

26. The semiconductor package of claim 25, wherein the encapsulation layer encapsulates the first integrated circuit die and the wireless tag.

27. The semiconductor package of claim 23, wherein the encapsulation layer comprises a transparent encapsulation layer.

28. The semiconductor package of claim 23, wherein the package substrate comprises a cavity in which the first integrated circuit die is housed, the semiconductor package further comprising a package lid sealing the cavity; and wherein the wireless tag is attached to a surface of the package substrate surrounding the package lid, the opening in the metal film of the antenna having a size sufficient to expose the package lid.

29. The semiconductor package of claim 28, wherein the encapsulation layer encapsulates the wireless tag only.

30. The semiconductor package of claim 23, wherein the antenna is formed of a monolithic metal film.

31. The semiconductor package of claim 30, wherein the metal film of the antenna is formed of a material selected from copper or aluminum or other conductive metal or alloy films.

32. The semiconductor package of claim 23, wherein the second integrated circuit die of the wireless element is affixed to the antenna through flip-chip attachment.
